(19) United States
(12) Patent Application Publication
(10) Pub. No.: US 2016/0003924 A1
(43) Pub. Date: Jan. 7, 2016

(54) SYSTEMS AND METHODS FOR MAGNETIC FIELD DETECTION

(71) Applicants: Matteo RINALDI, Brookline, MA (US); Nian-Xiang SUN, (US); Tianxiang NAN, (US); Yu HUI, Malden, MA (US); NORTHEASTERN UNIVERSITY, Boston, MA (US)

(72) Inventors: Nian-Xiang Sun, Winchester, MA (US); Matteo Rinaldi, Brookline, MA (US); Tianxiang Nan, Watertown, MA (US); Yu Hui, Malden, MA (US)

(21) Appl. No.: 14/771,460

(22) PCT Filed: Mar. 6, 2014
(86) PCT No.: PCT/US14/21152

§ 371 Date: Aug. 28, 2015

Related U.S. Application Data
(60) Provisional application No. 61/773,993, filed on Mar. 7, 2013.

(51) Int. Cl. G01R 33/28; G01R 33/00

(52) U.S. Cl. CPC G01R 33/28; G01R 33/0052

(57) ABSTRACT

This disclosure provides systems, methods, and apparatus for detecting magnetic fields. A magnetic sensor can include a substantially planar magnetostrictive layer. A piezoelectric layer can be bonded to a lower surface of the magnetostrictive layer. An electrode layer can be bonded to a lower surface of the piezoelectric layer. The device can be configured such that, when exposed to a magnetic field, at least one of an admittance amplitude, a quality factor, and a resonant frequency of the device is altered. The device can have a resonant frequency in the range of about 1 MHz to about 100 GHz.

### STATEMENT OF GOVERNMENT FUNDING

This invention was made with funding from United States Grant from the National Science Foundation NSF CAREER Grant No. 0746810. The United States Government may have certain rights to this invention.

### BACKGROUND

Resonant magnetic field sensors can be based on field induced resonance frequency variation of microcantilever resonators with incorporated magnetic materials. Such devices typically have relatively low electromechanical performance and relatively low magnetostrictive coupling. Therefore, these devices can show limited values of sensitivity and can require the use of complex actuation and sensing mechanisms. Moreover, such devices are generally based on low frequency (e.g., less than 500 KHz) resonant structures, which limits both sensitivity and power handling of the resonant sensor.

### SUMMARY

The systems, methods, and devices of the disclosure each have several innovative aspects, no single one of which is solely responsible for the desirable attributes disclosed herein.

One innovative aspect of the subject matter described in this disclosure can be implemented in a device for detecting a magnetic field. The device can include a substrate forming two support structures. The device can include a resonator suspended between the two support structures. The resonator can include a substantially planar magnetostrictive layer. The resonator can include a piezoelectric layer having an upper surface bonded to a lower surface of the magnetostrictive layer. The resonator can include an electrode layer having an upper surface bonded to a lower surface of the piezoelectric layer. The device can be configured such that, when exposed to a magnetic field, at least one of an admittance amplitude, a quality factor, and a resonant frequency of the resonator is altered. The resonator can have a frequency in the range of about 1 MHz to about 100 GHz.

In some implementations, the device can include means for determining at least one of the admittance amplitude of the device, the quality factor of the device, and the resonant frequency of the device.

In some implementations, a thickness of the piezoelectric layer can be selected to be substantially equal to the thickness of the magnetostrictive layer.

In some implementations, each of the magnetostrictive layer and the piezoelectric layer can have a thickness in the range of about 50 nanometers to about 500 nanometers.

In some implementations, the electrode layer can include an interdigitated transducer.

In some implementations, the magnetostrictive layer can be formed from iron-gallium-boron from aluminum nitride (AlN). In some implementations, the electrode layer can be formed from platinum (Pt).

In some implementations, each of the magnetostrictive layer, the piezoelectric layer, and the electrode layer can have a length in the range of about 1 micron to about 5 millimeters. In some implementations, each of the magnetostrictive layer, the piezoelectric layer, and the electrode layer has a width substantially equal to have of its length.

Another aspect of the subject matter described in this disclosure can be implemented in a method for manufacturing a magnetic field detection device. The method can include providing a substantially planar and electrically insulating substrate. The method can include depositing a layer of electrically conductive material over the substrate. The method can include depositing a layer of piezoelectric material over the electrically conductive material. The method can include depositing a layer of magnetostrictive material over the piezoelectric material. The method can include removing at least a portion of the substrate.

In some implementations, depositing the layer of electrically conductive material can further include sputter-depositing the layer of conductive material and patterning the electrically conductive material to form an interdigitated transducer.

In some implementations, the method can include etching the piezoelectric layer to form vias exposing the electrically conductive layer.

In some implementations, the method can include depositing gold over the exposed portion of the electrically conductive layer to form an electrode. In some implementations, the gold can be deposited to a thickness in the range of about 40 nanometers to about 60 nanometers.

In some implementations, the method can include applying a magnetic field during the step of depositing the layer of magnetostrictive material, the magnetic field selected to orient magnetic domains of the magnetostrictive material. The magnetic field can be oriented along a width of the magnetic field detection device. In some implementations, the magnetic field can be in the range of about 15 Oe to about 25 Oe.

In some implementations, the method can include the step of etching the piezoelectric layer to define a resonant nano-plate of the magnetic field detection device.

In some implementations, the substrate can be removed using xenon difluoride (XeF₂) as an etchant.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows a perspective view of a magnetic field detection device, according to an illustrative implementation.

FIG. 1B shows an exploded view of the magnetic field detection device shown in FIG. 1A, according to an illustrative implementation.

FIGS. 2A-2C show graphs of the admittance amplitude, Butterworth-van Dyke fit, and resonance frequency of an exemplary magnetic field detection device, according to an illustrative implementation.

FIGS. 3 shows a flow diagram of a process for manufacturing a magnetic field detection device, according to an illustrative implementation.

FIGS. 4A-4E show cross-sectional views of a magnetic field detection device at various stages of the manufacturing process shown in FIG. 3, according to an illustrative implementation.

Like reference numbers and designations in the various drawings indicate like elements.

### DETAILED DESCRIPTION

Following below are more detailed descriptions of various concepts related to, and implementations of, systems and methods for magnetic field detection. The various concepts introduced above and discussed in greater detail below may be implemented in any of numerous ways, as the described concepts are not limited to any particular manner of implementation. Examples of specific implementations and applications are provided primarily for illustrative purposes.

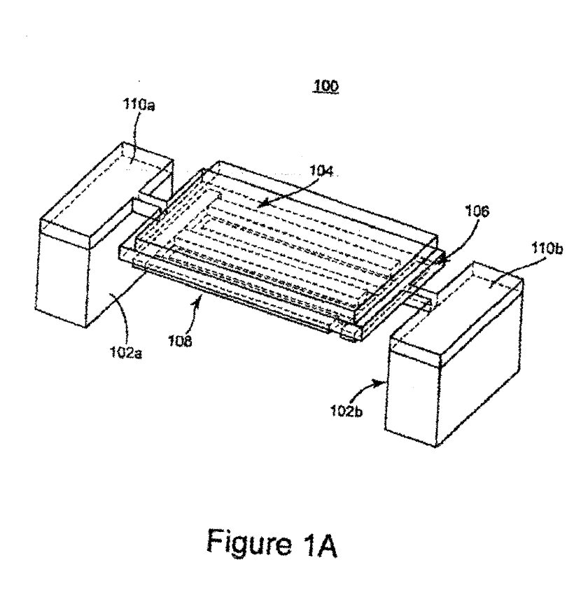

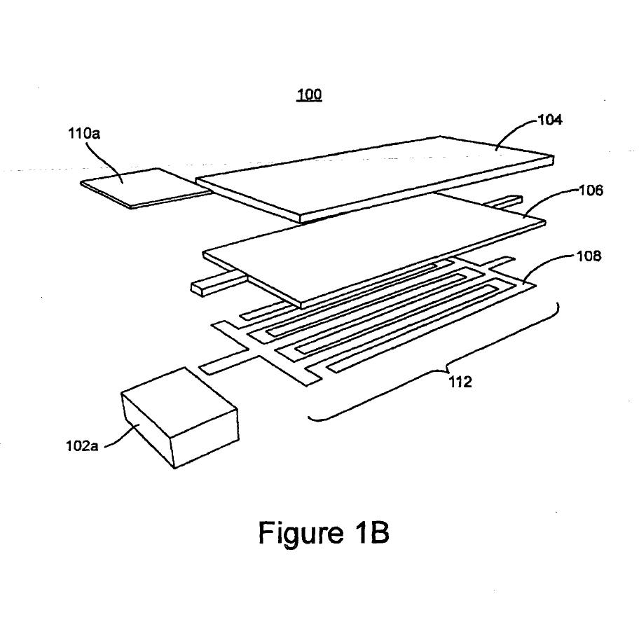

FIG. 1A shows a perspective view of a magnetic field detection device 100, according to an illustrative implementation. The magnetic field detection device 100 is suspended between two support structures 102a and 102b formed from a substrate material (generally referred to as support structures 102). The device 100 includes an upper magnetostrictive layer 104, a piezoelectric layer 106 adjacent to and in contact with the magnetostrictive layer 104, and an electrode layer 108 adjacent to and in contact with the piezoelectric layer 106. Electrode pads 110a and 110b (generally referred to as electrode pads 110) are formed atop the substrate support structures 102a and 102b, respectively. The electrode pads 110 are coupled to the piezoelectric layer 106 of the device 100.

The device 100 can take advantage of the piezoelectric effect and magnetostriction to detect a presence of a magnetic field. Piezoelectricity is an energy conversion process by which mechanical energy can be converted into electrical energy, and vice versa. When mechanical energy is applied across a piezoelectric material, such as the piezoelectric layer 106, an electrical voltage can be generated across the piezoelectric material 106. The resulting voltage is directly proportional to the amount of mechanical energy applied to the piezoelectric material. Therefore, measurement of the resulting voltage can be used to determine the amount of mechanical energy applied to the piezoelectric material. The physical mechanism of piezoelectric behavior is a function of the crystallography, domain, and other microstructures of the piezoelectric material.

Similarly, magnetostriction is a property of some materials (such as the magnetostrictive layer 104 of the device 100) that causes the materials to physically deform during the process of magnetization. Magnetostrictive materials have a structure that is divided into domains. Each domain is a region of uniform polarization. When a magnetostrictive material is exposed to a magnetic field, the domains rotate and their boundaries shift, which can cause internal strain in the material, resulting in a change in the dimensions of the material.

The device 100 can make use of the magnetostrictive and piezoelectric behavior of the magnetostrictive layer 104 and the piezoelectric layer 106 to detect a magnetic field. For example, when the device 100 is exposed to a magnetic field, the shifting of the domain boundaries within the magnetostrictive layer 104 can cause the magnetostrictive layer 104 to change its shape. As discussed above, the magnetostrictive layer 104 is adjacent to and in contact with the piezoelectric layer 106. In some implementations, the magnetostrictive layer 104 is bonded to the piezoelectric layer 106 so as to cause strong mechanical coupling of the magnetostrictive layer 104 and the piezoelectric layer 106. As a result, in response to the applied magnetic field, the deformation of the magnetostrictive layer 104 applies a stress to the piezoelectric layer 106, which can cause deformation of the piezoelectric layer 106. Deformation of the piezoelectric layer 106, in turn, can cause a voltage to be generated across the piezoelectric layer 106. This voltage can be detected, for example, by probing the electrode pads 110a and 110b with a voltmeter. In some implementations, other electrical or physical characteristics of the device 100, such as its electrical admittance or resonance frequency, may be altered by the presence of a magnetic field. Thus, a magnetic field in the vicinity of the device 100 can be detected by monitoring its electrical and physical properties.

In some implementations, the magnetostrictive layer 104 can be formed from iron-gallium-boron (FeGaB). In other implementations, suitable material exhibiting magnetostrictive behavior such as CoFeSiB, FeGa, etc. may be used to form the magnetostrictive layer 104. The piezoelectric layer 106 can be formed from aluminum nitride (AlN) or from any other suitable piezoelectric material, such as ZnO, lead zirconate titanate (PZT), barium strontium titanate (BST), barium titanate (BT), etc. Electrically conductive material can be used to form the electrode layer 108 and the electrode pads 110. For example, in some implementations the electrode layer 108 can be formed from platinum (Pt) and the electrode pads 110 can be formed from gold (Au). To prevent electrical interference, the substrate support structures 102 can be high resistivity Si, or other electrically insulating material.

As shown in FIG. 1A, the magnetostrictive layer 104, the piezoelectric layer 106, and the electrode layer 108 can each have a substantially rectangular shape and can be stacked on top of one another to form a resonator. The resonator can be suspended between the substrate support structures 102 so that it is mechanically decoupled from the material used to form the substrate support structures 102. Therefore, the resonator can vibrate freely in response to an applied force. For example, in some implementations, the magnetostriction and piezoelectric behavior of the magnetostrictive layer 104 and the piezoelectric layer 106 that form the resonator can cause the resonator to deform in response to an applied magnetic field, as discussed above. In some implementations, the applied magnetic field can be a time-varying magnetic field. Resonance of the resonator may be achieved when the frequency of such a magnetic field matches the resonant frequency of the resonator. In some implementations, the resonant frequency of the resonator may be altered by altering the dimensions of the magnetostrictive layer 104 and the piezoelectric layer 104 which form the resonator. For example, these dimensions may be altered by the application of a magnetic field or an electrical voltage, as discussed above.

FIG. 1B shows an exploded view of the magnetic field detection device 100 shown in FIG. 1A, according to an illustrative implementation. The exploded view shows the magnetostrictive layer 104, the piezoelectric layer 106, and the electrode layer 108 spaced apart from one another so that the physical details of each layer may be illustrated more clearly. As shown, the electrode layer 108 includes an interdigitated electrode transducer (IDT) 112 formed from two pieces of material that make up the electrode layer 108. the IDT 112 includes seven finger electrodes. In some implementations, the resonant frequency of the device 100 can be determined in part by the pitch of the finger electrodes of the IDT 112, along with other mechanical properties of the magnetostrictive layer 104 and the piezoelectric layer 104. For example, The resonance frequency of the resonator can be expressed as

$${f}_{0} = \frac{1}{2 {W}_{0}} \sqrt{\frac{{E}_{eq}}{{ρ}_{eq}}} ,$$

with W₀ being the pitch of the finger electrodes forming the IDT 112, E_{eq} the equivalent Young's Modulus and ρ_{eq} the equivalent density of the resonator.

The components of the device 100 can be fabricated using nano-scale processes, resulting in a very small form factor for the device 100. In some implementations, the magnetostrictive layer 104 and the piezoelectric layer 106 can each have a thickness in the range of about 50 nm to about 500 nm. In further implementations, the magnetostrictive layer 104 and the piezoelectric layer 106 can each have a thickness in the range of about 100 nm to about 400 nm. In still further implementations, the magnetostrictive layer 104 and the piezoelectric layer 106 can each have a thickness in the range of about 200 nm to about 300 nm. In some implementations, the thickness of the magnetostrictive layer 104 and the piezoelectric layer 104 can be selected to be substantially equal. For example, this can increase the magnetoelectric coupling of the magnetostrictive layer 104 and the piezoelectric layer 104, which can result in enhanced performance of the device 100.

In some implementations, the overall device 100 can have a length in the range of about 1 micron to about 10 mm. In further implementations, the overall device 100 can have a length in the range of about 5 microns to about 5 mm. In still further implementations, the overall device 100 can have a length in the range of about 10 microns to about 1 mm. In yet further implementations, the overall device 100 can have a length in the range of about 50 microns to about 1 mm. In further implementations, the overall device 100 can have a length in the range of about 100 microns to about 500 microns. Such small scale for the device 100 can result in relatively high resonant frequencies for the resonator. For example, in some implementations, the resonant frequency can be in the range of about 1 MHz to about 100 GHz. In further implementations, the resonant frequency can be in the range of about 10 MHz to about 10 GHz. In still further implementations, the resonant frequency can be in the range of about 100 MHz to about 1 GHz. High resonant frequency can increase the performance and sensitivity of the device 100 as compared to other devices having lower resonant frequencies.

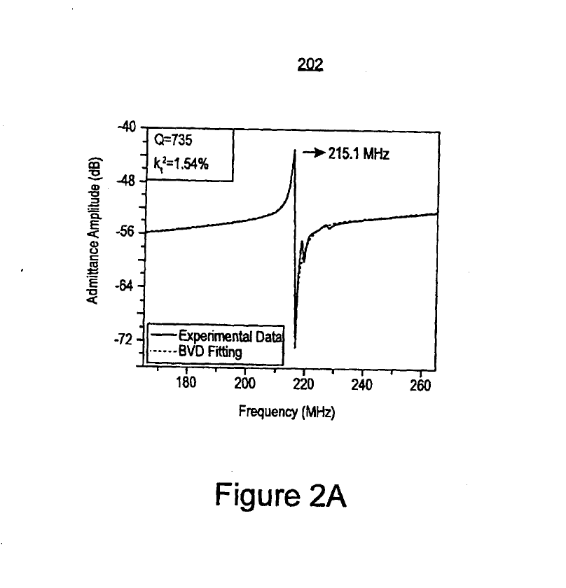

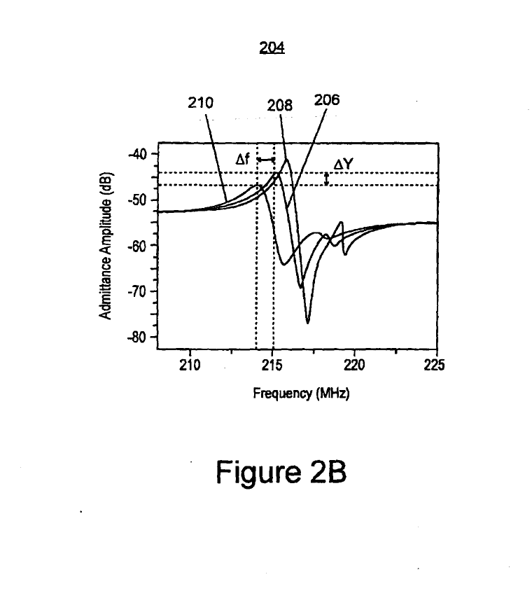

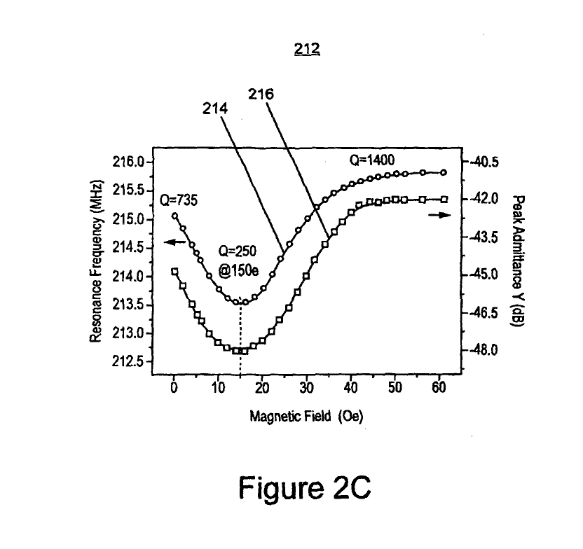

FIGS. 2A-2C show graphs of the admittance amplitude, Butterworth-van Dyke fit, and resonance frequency of an exemplary magnetic field detection device, according to an illustrative implementation. The device whose characteristics are shown in FIGS. 2A-2C is similar to the device 100 shown in FIGS. 1A-1B. For example, the device includes a magnetostrictive layer formed from FeGaB, a piezoelectric layer formed from MN, and an IDT formed from platinum. The magnetostrictive layer, the piezoelectric layer, and the IDT form a resonator having a length of about 200 microns and a width of about 100 microns. The magnetostrictive layer and the piezoelectric layer each have a thickness of about 250 nm, and the IDT has a thickness of about 50 nm. Silicon was used to form the substrate support structures of the device. The device has an electromechanical resonance frequency of about 215 MHz.

FIG. 2A shows a graph 202 of the admittance curve and the Butterworth-van Dyke (BVD) model fitting of the device. Both curves are shown, however the BVD fit is so close to the measured data that the two curves substantially overlap. A quality factor Q of 735 in air was extracted from the BVD fitting at zero bias magnetic field. By comparison, the quality factors of different magnetic sensor devices operating at relatively low frequencies can typically be around 100. The magnetostrictive layer acts as a floating electrode and provides good confinement of the electric field within the entire thickness of piezoelectric layer, which results in a high electromechanical coupling coefficient kₜ² of about 1.54%.

Strong magnetoelectric coupling in the magnetostrictive layer and piezoelectric layer of the resonator was demonstrated. A DC bias field induced change in the electromechanical resonance frequency, which was attributable to the bias magnetic field-induced Young's modulus change in the magnetostrictive material. FIG. 2B shows a graph 204 of the admittance curves 206, 208, and 210 of the device at various DC bias magnetic fields applied along the length direction of the resonator. The curves 206, 208, and 210 represents data obtained using DC biases of 0 Oe, 15 Oe and 60 Oe, respectively. FIG. 2C shows a graph 212 of the resonant frequency curve 214 and peak admittance curve 216, based on the data presented in the graph 204 shown in FIG. 2B. Both resonance frequency f, and peak admittance amplitude Y, exhibited a trend similar to the trend with DC bias magnetic field, which first decreased with the increase of bias field, reaching minimum values at a bias field of 15 Oe, and then increased until the magnetostrictive layer was saturated at around 50-60 Oe. From the BVD fitting results shown in FIG. 2A, the quality factor Q followed a similar trend starting from about 735 (0 Oe), reaching the minimum value of 250 at the transition magnetic field (15 Oe), and finally saturating to about 1400 at high magnetic fields (>60 Oe). The variation of the quality factor can be attributed to the magnetic loss associated with magnetic domain wall activities which were significantly reduced when high magnetic field was applied and the magnetic domain walls was eliminated. As discussed above, the resonance frequency of the magnetoelectric NEMS resonator can be expressed by

$${f}_{0} = \frac{1}{2 {W}_{0}} \sqrt{\frac{{E}_{eq}}{{ρ}_{eq}}}$$

with W₀ being the pitch of the finger electrodes forming the interdigital transducer (IDT), E_{eq} the equivalent Young's Modulus and ρ_{eq} the equivalent density of the resonator. A magnetostrictive strain can be induced in the magnetostrictive layer under a DC magnetic field through the delta-E effect, which led to a changed Young's modulus of the magnetostrictive layer, and therefore a changed equivalent Young's modulus of the resonator. Thus the electromechanical resonance frequency and the admittance amplitude of the piezoelectric layer were varied through DC magnetic fields. The admittance amplitude at the resonance frequency has a similar trend to resonance frequency change due to the variation of the quality factor and the resonance frequency. The lowest resonance frequency of the device happened when the bias magnetic field was around 15 Oe, which is close to the bias field needed for reaching the highest piezomagnetic coefficient of the magnetostrictive material.

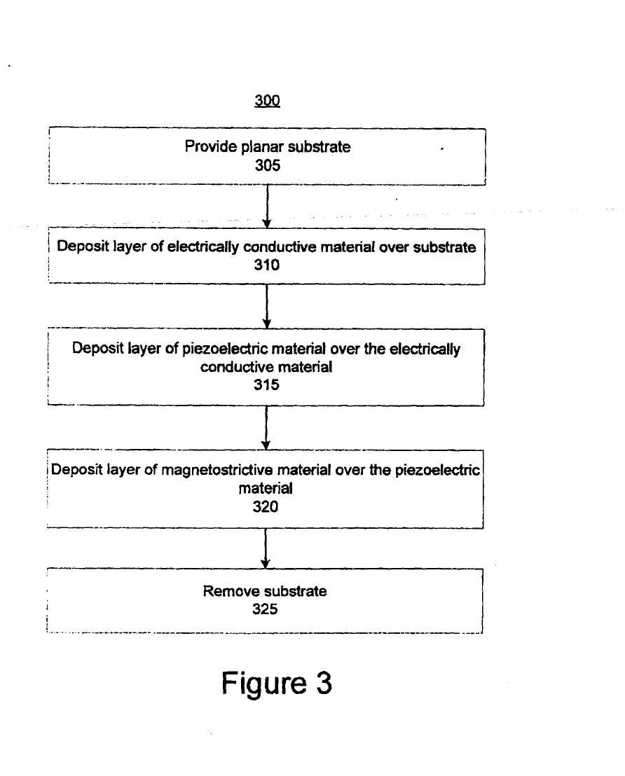

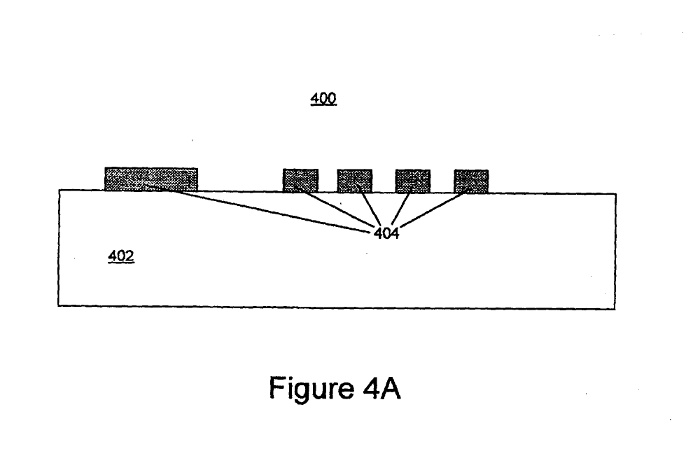

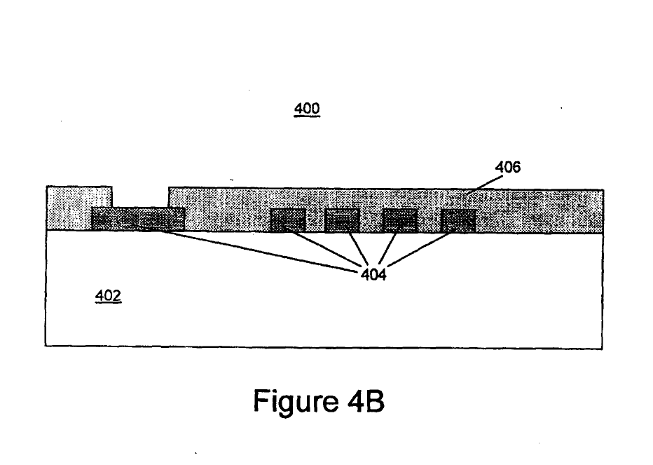

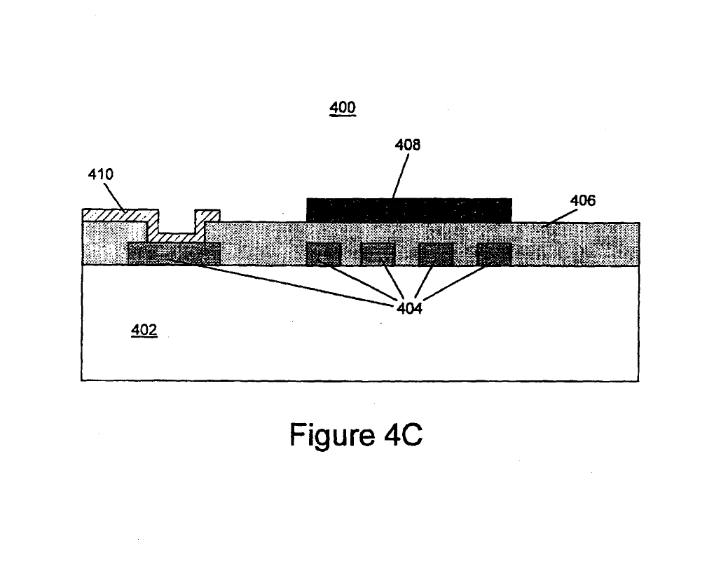

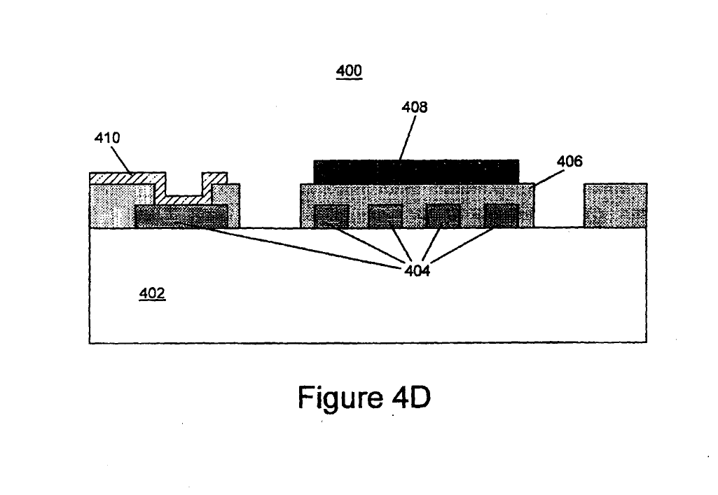

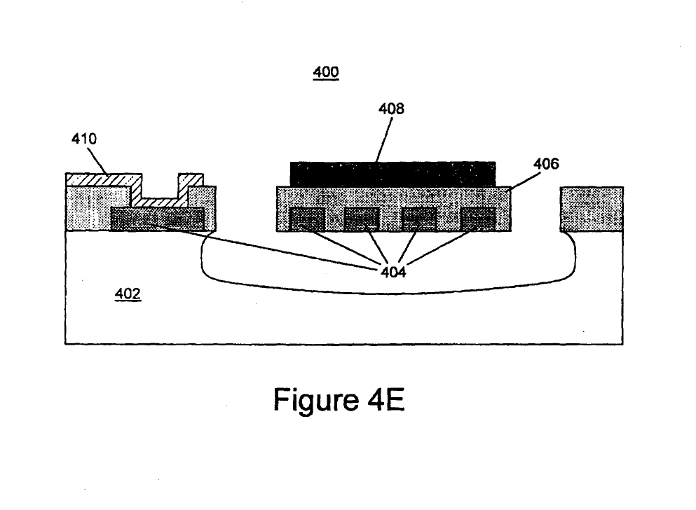

FIGS. 3 shows a flow diagram of a process 300 for manufacturing a magnetic field detection device, according to an illustrative implementation. FIGS. 4A-4E show-cross sectional views of a magnetic field detection device 400 at various stages of the manufacturing process shown in FIG. 3, according to an illustrative implementation. FIGS. 3 and 4A-4E will be discussed together below. In some implementations, the device 400 shown in FIGS. 4A-4E can be similar to the device 100 shown in FIGS. 1A-1B. In brief overview, the process 300 includes providing a substantially planar substrate (stage 305), depositing a layer of electrically conductive material over the substrate (stage 310), depositing a layer of piezoelectric material over the electrically conductive material (stage 315), depositing a layer of magnetostrictive material over the piezoelectric material (stage 320), and removing at least a portion of the substrate (stage 325).

Referring again to FIG. 3, the process 300 includes providing a substantially planar substrate (stage 305). In some implementations, the substrate can be formed from an electrically insulating material. Referring to FIG. 4A, a substrate 402 is shown having a substantially planar horizontal upper surface. Due to the small scale of the device 400 (i.e., dimensions measured in nanometers), precision in the manufacturing process 300 can be useful for enhancing the performance of the device 400. For example, the substantially planar shape of the substrate 402 can help to ensure that the components of the device 400 that are built on top of the substrate 402 also retain substantially planar surfaces.

The process 300 includes depositing a layer of electrically conductive material over the substrate (stage 310). In some implementations, the electrically conductive material can include gold or platinum. The layer of electrically conductive material can form an electrode layer on the bottom surface of a resonator of the device. In some implementations, depositing the layer of conductive material can include deposition by a MEMS or NEMS process, such as sputter deposition. In some implementations, the process 300 can also include patterning the deposited electrically conductive material to define an IDT. For example, the electrically conductive material can be patterned to form an IDT similar to the IDT formed in the electrode layer 108 of the device 100 shown in FIG. 1. FIG. 4A shows the electrically conductive material 404 that has been deposited onto the substrate 402. The electrically conductive material 404 has been patterned to form several finger electrodes of the IDT, four of which are shown in the cross-sectional view of FIG. 4A. Patterning the electrically conductive material also results in the formation of the bottom portion of an electrode pad separate from the resonator, which can be supported by the substrate support structures when the device 400 is completed.

The process 400 includes depositing a layer of piezoelectric material over the electrically conductive material (stage 315). In some implementations, the piezoelectric material can include MN or any other suitable material that exhibits piezoelectric behavior. In implementations in which the layer of electrically conductive material has been patterned, the piezoelectric material can be deposited directly over the electrically conductive material and onto the exposed portions of the substrate material below. In some implementations, the piezoelectric material can be deposited to a thickness in the range of about 50 nm to about 500 nm. In further implementations, the piezoelectric material can be deposited to a thickness in the range of about 100 nm to about 400 nm. In still further implementations, the piezoelectric material can be deposited to a thickness in the range of about 200 nm to about 300 nm. In some implementations, the process 300 can include etching the layer of piezoelectric material to define one or more vias exposing a portion of the electrically conductive layer. For example, FIG. 4B shows the piezoelectric material 406 that has been deposited over the electrically conductive layer 404 and patterned to form a via over the leftmost portion of the electrically conductive material 404.

The process 300 includes depositing a layer of magnetostrictive material over the piezoelectric material (stage 320). In some implementations, the magnetostrictive material can include FeGaB, however any other suitable material exhibiting magnetostrictive properties may be used. The magnetostrictive material be deposited by physical vapor deposition. In some implementations, the magnetostrictive material can be deposited to a thickness in the range of about 50 nm to about 500 nm. In further implementations, the magnetostrictive material can be deposited to a thickness in the range of about 100 nm to about 400 nm. In still further implementations, the magnetostrictive material can be deposited to a thickness in the range of about 200 nm to about 300 nm. The thickness of the magnetostrictive material can be selected to match the thickness of the electrically conductive layer. In some implementations, the magnetostrictive material can be patterned, for example by liftoff, to remove the portion of the magnetostrictive layer that is not required for the resonator. For example, the magnetostrictive layer can be patterned to a define a resonator positioned directly above the finger electrodes of the IDT formed in the electrically conductive layer. FIG. 4C shows a magnetostrictive layer 400 that has been deposited and patterned. As shown, the magnetostrictive material not removed during the patterning process can be directly aligned with the finger electrodes formed from the electrically conductive material 404. In some implementations, the process 300 can include applying a magnetic field during the step of depositing the magnetostrictive material (stage 320). For example, the magnetic field can be selected to pre-orient the magnetic domains of the device 400. In some implementations, the magnetic field can be applied along a length or width of the device 400.

In some implementations, the process 300 can also include depositing a second electrically conducting material over a via formed in the piezoelectric layer to cover the exposed portion of the electrically conducting material deposited in stage 310. For example, the second electrically conductive material can form an electrode pad similar to the electrode pads 110 shown in FIGS. 1A-1B. In some implementations, the second electrically conductive material can include gold and can be deposited to a thickness in the range of about 10 nm to about 100 nm. In further implementations, the second electrically conductive material can be deposited to a thickness in the range of about 20 nm to about 80 nm. In still further implementations, the second electrically conductive material can be deposited to a thickness in the range of about 30 nm to about 70 nm. In yet further implementations, the second electrically conductive material can be deposited to a thickness in the range of about 40 nm to about 60 nm. FIG. 4C shows an electrode pad 410 that has been deposited over the piezoelectric material 406 to cover the electrically conductive material 404 exposed by a via in the piezoelectric material 406.

In some implementations, the process 300 can include etching the piezoelectric material to further define the resonator. For example, the piezoelectric material may be etched by inductively coupled plasma etching. The device 400 as it appears after the piezoelectric layer 400 has been etched is shown in FIG. 4D.

The process 300 also includes removing at least a portion of the substrate (stage 325). In some implementations, the portion of the substrate directly beneath the resonator (i.e., directly beneath the IDT) can be removed so that vibration of the resonator is unobstructed by the substrate. The substrate can be removed, for example, by a xenon difluoride (XeF₂) isotropic etching process. In some implementations, a portion of the substrate may not be etched away. For example, the portion of the substrate that remains after the etching process can form the structural supports 110 shown in FIGS. 1A-1B. A cross-sectional view of the final version of the device 400 as it appears after a portion of the substrate 402 has been removed is shown in FIG. 4E.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

What is claimed is:

1. A device for detecting a magnetic field, the device comprising:
a substrate forming two support structures;
a resonator suspended between the two support structures, the resonator comprising:
a substantially planar magnetostrictive layer;
a piezoelectric layer having an upper surface bonded to a lower surface of the magnetostrictive layer; and
an electrode layer having an upper surface bonded to a lower surface of the piezoelectric layer, wherein:
the device is configured such that, when exposed to a magnetic field, at least one of an admittance amplitude, a quality factor, and a resonant frequency of the resonator is altered; and
the resonator has a resonant frequency in the range of about 1 MHz to about 100 GHz.

2. The device of claim 1, further comprising means for determining at least one of the admittance amplitude of the device, the quality factor of the device, and the resonant frequency of the device.

3. The device of claim 1, wherein a thickness of the piezoelectric layer is selected to be substantially equal to the thickness of the magnetostrictive layer.

4. The device of claim 3, wherein each of the magnetostrictive layer and the piezoelectric layer has a thickness in the range of about 50 nanometers to about 500 nanometers.

5. The device of claim 1, wherein the electrode layer comprises an interdigitated transducer.

6. The device of claim 1, wherein the magnetostrictive layer is formed from iron-gallium-boron (FeGaB).

7. The device of claim 1, wherein the piezoelectric layer is formed from aluminum nitride (AlN).

8. The device of claim 1, wherein the electrode layer is formed from platinum (Pt).

9. The device of claim 1, wherein each of the magnetostrictive layer, the piezoelectric layer, and the electrode layer has a length in the range of about 1 micron to about 5 millimeters.

10. The device of claim 1, wherein each of the magnetostrictive layer, the piezoelectric layer, and the electrode layer has a width substantially equal to have of its length.

11. A method for manufacturing a magnetic field detection device, the method comprising:
providing a substantially planar and electrically insulating substrate;
depositing a layer of electrically conductive material over the substrate;
depositing a layer of piezoelectric material over the electrically conductive material;
depositing a layer of magnetostrictive material over the piezoelectric material; and
removing at least a portion of the substrate;

12. The method of claim 11, wherein depositing the layer of electrically conductive material further comprises sputter-depositing the layer of conductive material and patterning the electrically conductive material to form an interdigitated transducer.

13. The method of claim 11, further comprising etching the piezoelectric layer to form vias exposing the electrically conductive layer.

14. The method of claim 13, further comprising depositing gold over the exposed portion of the electrically conductive layer to form an electrode.

15. The method of claim 14, wherein the gold is deposited to a thickness in the range of about 40 nanometers to about 60 nanometers.

16. The method of claim 11, further comprising applying a magnetic field during the step of depositing the layer of magnetostrictive material, the magnetic field selected to orient magnetic domains of the magnetostrictive material.

17. The method of claim 16, wherein the magnetic field is oriented along a width of the magnetic field detection device.

18. The method of claim 16, wherein the magnetic field is in the range of about 15 Oe to about 25 Oe.

19. The method of claim 11, further comprising the step of etching the piezoelectric layer to define a resonant nano-plate of the magnetic field detection device.

20. The method of claim 11, wherein the substrate is removed using xenon difluoride (XeF₂) as an etchant.
